(19) United States
(12) Patent Application Publication
(10) Pub. No.: US 2024/0378334 A1
(43) Pub. Date: Nov. 14, 2024

(54) IMPLEMENTING VEHICLE COLLISION SIMULATION SANDBOX

(71) Applicant: International Business Machines Corporation, Armonk, NY (US)

(72) Inventors: Jie JIANG, Ningbo (CN); Xiao Xia MAO, Shanghai (CN); Di XU, Shanghai (CN); Jialei MA, Shanghai (CN); Wen Ting LI, Shanghai (CN); Xiao Feng JI, Shanghai (CN)

(21) Appl. No.: 18/313,965

(22) Filed: May 8, 2023

(51) Int. Cl. G06F 30/15; B60Q 9/00

(52) U.S. Cl. CPC G06F 30/15; B60Q 9/008; B60W 60/0027

(57) ABSTRACT

Embodiments of the present disclosure provide systems and methods for implementing an intelligent vehicle-collision simulation sandbox and intelligently analyzing behaviors of surrounding objects with a current vehicle to simulate possible collisions of the current vehicle and surrounding objects and display intelligently calculated collision probabilities of the surrounding objects.

### BACKGROUND

The present invention relates to digital data processing, and more specifically, to systems and methods for implementing an intelligent vehicle-collision simulation sandbox.

Automobile manufacturers and technology companies expect to release semi-autonomous or fully autonomous vehicles in the near future. A need exists for new techniques to enable driverless vehicles to safely navigate their surroundings, which is both a technically complex and challenging endeavor. New techniques are needed to intelligently identify collision probabilities of an autonomous vehicle with surrounding objects to enable enhanced safety.

### SUMMARY

Embodiments of the present disclosure provide systems and methods for implementing an intelligent vehicle-collision simulation sandbox and intelligently analyzing behaviors of surrounding objects with a current vehicle to simulate possible collisions of the current vehicle and surrounding objects and display intelligently calculated collision probabilities of the surrounding objects.

A disclosed non-limiting method comprises generating a current vehicle-collision-simulation sandbox with a current vehicle centrally located and a surrounding object located relative to the current vehicle. The system forms a single-object slice sandbox for the surrounding object comprising an initial single-object slice for the surrounding object based on the current vehicle-collision-simulation sandbox. The system generates sequences of single-object slices for N times for the surrounding object based on the initial single-object slice for the surrounding object, where each generated sequence represents a most likely or probable relative displacement trajectory for the surrounding object to collide with the current vehicle. The single-object slices for each sequence are generated at a regular interval while the current vehicle is driving on a navigation route. The system, for each of the N sequences, calculates a corresponding collision probability of the surrounding object colliding with the current vehicle and selects a generated sequence including a smallest number of single-object slices for a possible vehicle collision of the surrounding object with the current vehicle and merges the single-object slices of the selected sequence to provide a representative displacement trajectory of the surrounding object. The system displays the collision probability and the representative displacement trajectory of the surrounding object with the current vehicle to a user of the current vehicle.

Other disclosed embodiments include a computer system and computer program product for implementing an intelligent vehicle-collision simulation sandbox, implementing features of the above-disclosed method.

### BRIEF DESCRIPTION OF THE DRAWINGS

FIG. 1 is a block diagram of an example computer environment for use in conjunction with one or more disclosed embodiments for implementing analysis, simulation and collision prediction of autonomous vehicles;

FIG. 2 is a block diagram of an example system for implementing analysis, simulation and collision prediction of autonomous vehicles using an intelligent vehicle-collision simulation sandbox of one or more disclosed embodiments;

FIG. 3 is a schematic and block diagram illustrating example operations of the system of FIG. 2 for implementing analysis, simulation and collision prediction of autonomous vehicles using an intelligent vehicle-collision simulation sandbox of one or more disclosed embodiments.

FIG. 4 is a schematic and block diagram illustrating example operations of the system of FIG. 2 to construct example sandboxes with the current vehicle driving along a navigation route using an intelligent vehicle-collision simulation sandbox of one or more disclosed embodiments;

FIGS. 5A and 5B together illustrate example operations of a method for implementing analysis, simulation and collision prediction of a current vehicle and surrounding objects of one or more disclosed embodiments;

FIG. 6 illustrates multiple example driving directions of an object for implementing analysis, simulation and collision prediction of one or more disclosed embodiments;

FIG. 7 is a schematic and block diagram illustrating example operations of the system of FIG. 2 for simulating collision using an intelligent vehicle-collision simulation sandbox of one or more disclosed embodiments;

FIGS. 8A, 8B, 8C and 8D together illustrate example operations for simulating collision to generate possible collision routes rendered as sequences of directions along which a surrounding object might collide into the current vehicle most directly and quickly based on a navigation route of the current vehicle of one or more disclosed embodiments;

FIG. 9 is a schematic and block diagram providing an example generator implementation structure of the system of FIG. 2 for implementing example operations for analysis, simulation and collision prediction of one or more disclosed embodiments;

FIG. 10 is a schematic and block diagram illustrating example operations of the system of FIG. 2 for implementing analysis, simulation and collision prediction of one or more disclosed embodiments;

FIG. 11 illustrates example values from the example operations of FIG. 10 of one or more disclosed embodiments;

FIG. 12 schematically illustrates example operations to build a training dataset based on historical vehicle collision data of one or more disclosed embodiments;

FIG. 13 is a flow chart illustrating example training operations of example encoder module of the system of FIG. 2 for implementing analysis, simulation and calculating collision probability of surrounding objects with a current vehicle of one or more disclosed embodiments;

FIG. 14 is a schematic and block diagram providing example operations of adversarial training of a discriminator and a generator of the system of FIG. 2 for simulating collision in an example sandbox using an intelligent vehicle-collision simulation sandbox of one or more disclosed embodiments;

FIG. 15 schematically illustrates example adversarial training operations with a policy gradient relying on an action value function of the system of FIG. 2 of one or more disclosed embodiments;

FIG. 16 illustrates an example partial structure for implementing the discriminator of one or more disclosed embodiments; and

FIG. 17 is a flow chart illustrating a method for implementing analysis, simulation and calculated collision probability of surrounding objects with a current vehicle of one or more disclosed embodiments.

### DETAILED DESCRIPTION

Embodiments of the present disclosure provide systems and methods for implementing a vehicle-collision-simulation sandbox for simulating each surrounding object colliding with a current vehicle in the sandbox and intelligently analyzing behaviors of surrounding objects (such as vehicles, pedestrians, motor bikes, and the like) to calculate collision probabilities of surrounding objects colliding with a current vehicle.

A non-limiting disclosed method comprises constructing a vehicle-collision-simulation sandbox for simulating a current vehicle with each surrounding object. In one embodiment, a single-object-displacement sequence generator (based on deep learning) is used to generate a number of sequences of single-object slices for a surrounding object in a single-object slice sandbox according to an initial single-object slice for the surrounding object. The single-object-displacement sequence generator can be trained with relative displacement trajectories of historical vehicle collisions that are used to generate sequences of single-object slices that a surrounding object could collide with the current vehicle in the sandbox. The system can exclude generated sequences that are irrational or impossible in the current road conditions and make the collision prediction more precise. A driving-direction-sequence construction module can construct driving-direction sequences of one or more possible or most-quickly-collision routes from the surrounding object to the current vehicle according to the real-time road data for a navigation route that can be provided to a single-object displacement sequence generator. The system can display a calculated collision probability for each surrounding object with the current vehicle to a user of the current vehicle. A fastest-collision-probability calculation module can be used to calculate the fastest collision probability for a generated sequence of single-object slices. A deviation-percentage calculation module can be used to calculate the average deviation percentage in the radial direction for a generated sequence of single-object slices for a surrounding object. A driving-direction-consistency analysis module can be used to determine driving direction consistency based on a generated sequence of single-object slices and a related input sequence of driving directions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the following, reference is made to embodiments presented in this disclosure. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.”

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

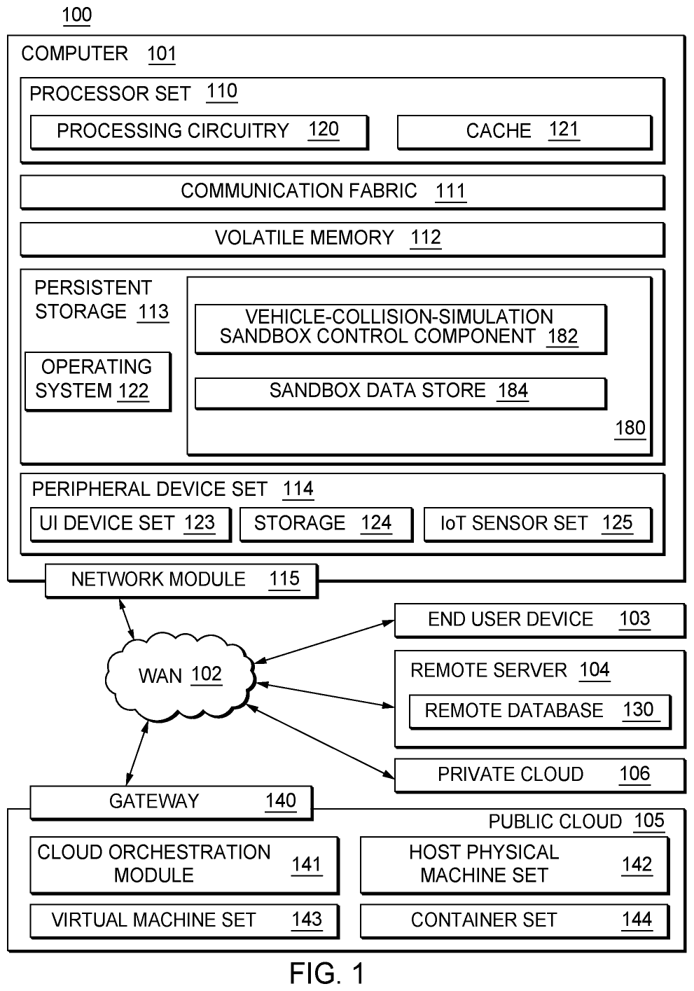

Referring to FIG. 1, a computing environment 100 contains an example of an environment for the execution of at least some of the computer code involved in performing the inventive methods, such as a Vehicle-Collision-Simulation Sandbox Control Component 182, and a Sandbox Data Store 184 at block 180. In addition to block 180, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 180, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 180 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 180 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economics of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Embodiments of the present disclosure provide new effective and efficient techniques for implementing an intelligent vehicle-collision simulation sandbox. A disclosed method and system intelligently analyze behaviors of surrounding objects with a current vehicle to simulate possible collisions of the current vehicle and surrounding objects and display intelligently calculated collision probabilities of the surrounding objects. A disclosed method comprises generating a current vehicle-collision-simulation sandbox with a current vehicle centrally located and one or more surrounding objects located relative to the current vehicle. The system forms a single-object slice sandbox for each of the surrounding objects comprising an initial single-object slice for the respective surrounding objects based on the current vehicle-collision-simulation sandbox. The system generates sequences of single-object slices for N times for each surrounding object based on the initial single-object slice for the respective surrounding object, where each generated sequence represents a most likely or probable relative displacement trajectory for the surrounding object to collide with the current vehicle. For example, the system generates single-object slices for each sequence at a regular interval while the current vehicle is driving on a navigation route. The system calculates, for each of the N sequences, a corresponding collision probability of the respective surrounding object with the current vehicle and selects a generated sequence including a smallest number of single-object slices for a possible vehicle collision of the surrounding object with the current vehicle. The system uses the single-object slices of the selected sequence with smallest number of single-object slices to obtain a representative displacement trajectory of that surrounding object. The system can display the collision probability and the representative displacement trajectory of the surrounding object with the current vehicle to a user of the current vehicle.

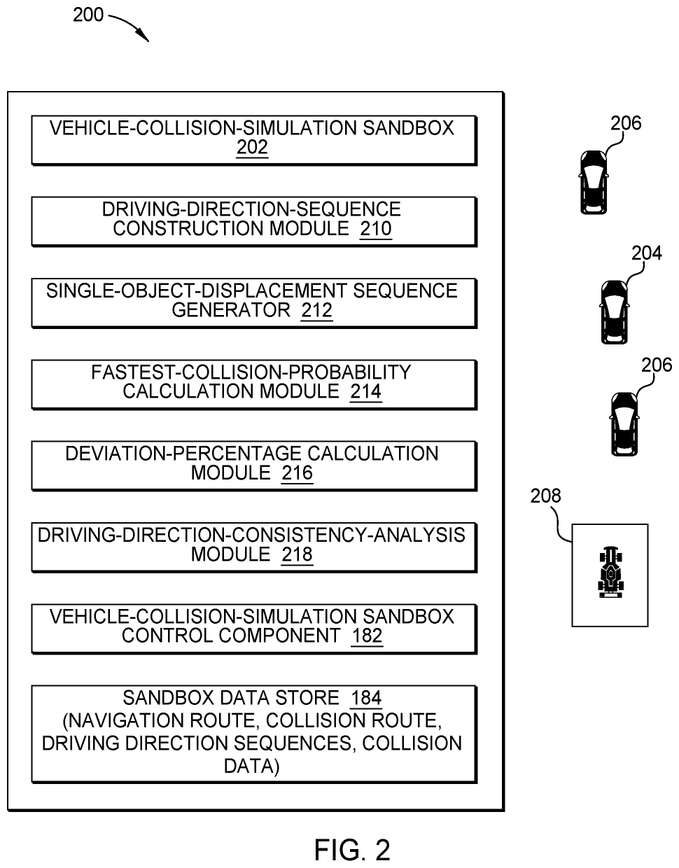

FIG. 2 illustrates an example system 200 for implementing analysis, simulation and collision prediction of autonomous vehicles of one or more disclosed embodiments. System 200 for example can be used in conjunction with the computer 101 and cloud environment of the computing environment 100 with the Vehicle-Collision-Simulation Sandbox Control Component 182 and the Sandbox Data Store 184 of FIG. 1 for implementing analysis, simulation and collision prediction of disclosed embodiments.

In a disclosed embodiment, system 200 uses a Vehicle-Collision-Simulation Sandbox 202 with the Vehicle-Collision-Simulation Sandbox Control Component 182 and the Sandbox Data Store 184 to simulate and display probabilities of a current vehicle 204 colliding with one or more surrounding objects 206. In a disclosed embodiment, system 200 can generate sandbox simulations of one or more virtual or historical collision objects 208, for example generated from a historical collision dataset of the Sandbox Data Store 184 to display historical collisions along the current navigation route to the user of the current vehicle.

Vehicle-Collision-Simulation Sandbox 202 can intelligently analyze behaviors of the surrounding objects 206 of the current vehicle 204 to efficiently and effectively simulate each surrounding object 206 colliding with the current vehicle 204. System 200 uses the Vehicle-Collision-Simulation Sandbox 202 to intelligently and efficiently simulate and display estimated collision probabilities of each surrounding object 206 colliding with the current vehicle 204 of disclosed embodiments.

In a disclosed embodiment, system 200 constructs the machine learning neural network Vehicle-Collision-Simulation Sandbox 202 used for intelligently analyzing behaviors of each of multiple surrounding objects 206 (e.g., other autonomous vehicles and manual vehicles, pedestrians, and the like) with the current vehicle 204 (e.g., autonomous car, truck, bus, or other motor vehicle). System 200 simulates predicted collisions of the current vehicle 204 with each surrounding object 206 and can display collision probabilities of the current vehicle 204 with each of the multiple surrounding objects 206 to the owner in the Vehicle-Collision-Simulation Sandbox 202. System 200 can display such collision probabilities for each surrounding object 206 together with the relative displacement trajectory of the first object 206 most likely to collide with the current vehicle 204.

System 200 includes a Driving-Direction-Sequence Construction Module 210 for estimating one or more sequences of driving directions of each of the surrounding objects 206 and the current vehicle 204 to predict a likely crash. In one disclosed embodiment, system 200 uses a Single-Object-Displacement Sequence Generator 212 (e.g., based on deep learning) to generate a sequence of single-object slices for a surrounding object in the sandbox according to the surrounding object's initial single-object slice.

In one disclosed embodiment, system 200 uses a Fastest-Collision-Probability Calculation Module 214 to calculate a collision probability based on a generated sequence of single-object slices. System 200 uses a Deviation-Percentage Calculation Module 216 to calculate the average deviation percentage in the radial direction for a generated sequence of single-object slices. System 200 uses a Driving-Direction-Consistency Analysis Module 218 to determine driving direction consistency based on a generated sequence of single-object slices and the related input sequence of driving directions of disclosed embodiments.

In accordance with features of disclosed embodiments, system 200 can simulate each surrounding object 206 colliding with the current vehicle 204 based on a calculated displacement trajectory and a calculated collision probability using the Vehicle-Collision-Simulation Sandbox 202. System 200 can visually demonstrate a displacement trajectory of a predicted collision step-by-step in the Vehicle-Collision-Simulation Sandbox 202, and the estimated collision probabilities can also be displayed.

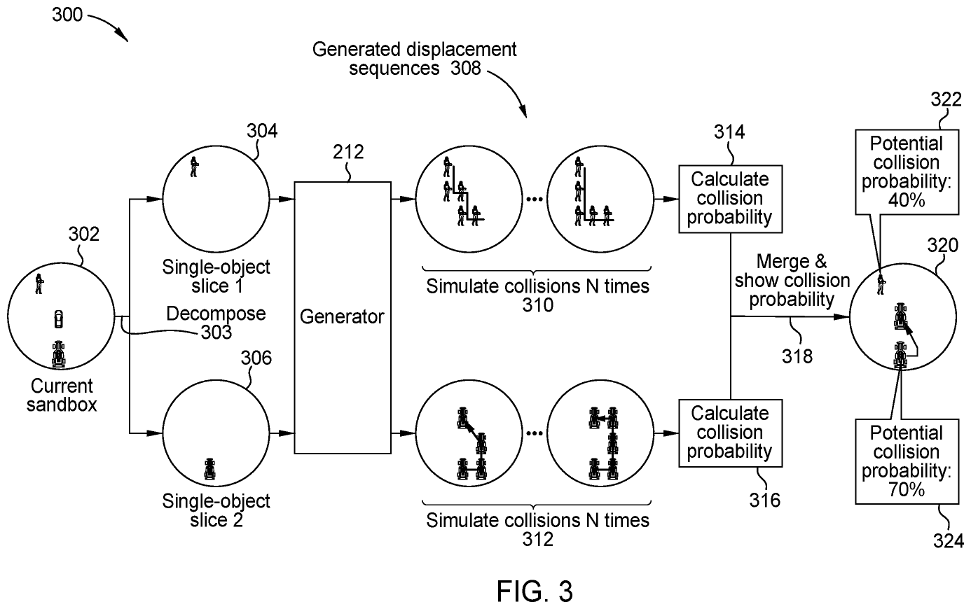

FIG. 3 provides a schematic and block diagram illustrating example operations 300 of the system 200 for implementing analysis, simulation and collision prediction of autonomous vehicles using an intelligent vehicle-collision simulation sandbox of one or more disclosed embodiments. An illustrated current vehicle-collision simulation sandbox 302 is, in this example, a grid-partitioned circular range including a current vehicle 204 with autonomous driving that is placed at the most centered grid and remains at the most centered grid location for all simulations. As shown, surrounding objects 206 are placed in a Vehicle-Collision-Simulation Sandbox 202, such as the current vehicle-collision simulation sandbox 302 at locations or grids where their respective geometric centers are located relative to the current vehicle 204.

For example, system 200 simulates the movement of each surrounding object 206 relative to the current vehicle 204 in a Vehicle-Collision-Simulation Sandbox 202. System 200 generates relative displacement trajectories based on historical vehicle collisions to intelligently simulate probable collisions of each surrounding object 206 with the current vehicle 204 in the sandbox as much as possible. Based on the simulation, a calculated collision probability of each surrounding object in the sandbox 202 can be shown to a user of the current vehicle 204, together with the relative displacement trajectory along which a first given object is most likely to collide with the current vehicle 204.

The current vehicle-collision simulation sandbox 302 is decomposed at the current time point into the respective initial single-object slices of included objects (e.g., by a decomposing module) as indicated at a line labeled Decompose 303. System 200 generates a single-object slice 1 304 for a surrounding object 206 (e.g., pedestrian) and a single-object slice 2 306 for another surrounding object 206 (e.g., vehicle) based on the initial single-object slices. The respective single-object slice 304, 306 is defined for example as a single-object slice sandbox 202 which includes only one of the surrounding objects 206 located relative to the current vehicle 204 in the single-object slice. To form each single-object slice 304, 306, system 200 places each respective surrounding object into an identical same grid in a blank sandbox 202 as the initial location in the current sandbox 302 and binds the respective single-object slice with the category and driving direction of that object. For example, each single-object slice 304, 306 can be bound with a given identified category (e.g., car, truck, motorcycle, bike, pedestrian, and the like) and a driving direction of the included surrounding objects 206. The Single-Object-Displacement Sequence Generator 212, for example shown as Generator 212 receives a respective initial single-object slice 304, 306. The Single-Object-Displacement Sequence Generator 212 generates simulated sequences according to the surrounding object's initial single-object slice, where each generated sequence represents a most likely or probable relative displacement trajectory that the surrounding object 206 could collide with the current vehicle 204. The Single-Object-Displacement Sequence Generator 212 generates displacement sequences 308 including simulated displacement sequences 310 for N times based on the initial single-object slice 304 from the decomposed current vehicle-collision simulation sandbox 302. The Single-Object-Displacement Sequence Generator 212 generates simulated displacement sequences 312 for N times based on the initial single-object slice 306 from the decomposed current vehicle-collision simulation sandbox 302. The Driving-Direction-Sequence Construction Module 210 can provide driving directions of each surrounding object 206 for the simulated displacement N sequences 310 and the simulated displacement N sequences 312. The trained generator 212 generates the N sequences of single-object slices for each surrounding object 206 to collide with the current vehicle in the generated sandboxes to a possible extent and with the fewest steps.

As shown at blocks 314, 316 for the generated N sequences 310, 312 of each object 206, system 200 calculates the corresponding collision probability. At the same time, system 200 selects the generated sequence including the smallest number of single-object slices, which could collide with the current vehicle and merge those single-object slices together to obtain the representative displacement trajectory for that object 206 if its collision probability is nonzero. As indicated at line 318 labeled Merge & show collision probability, system 200 displays a sandbox 320 with for example, a calculated potential collision probability 322 of 40%, for single-object slice 304 and a potential collision probability 324 of 70%, for single-object slice 306 to the user of the current vehicle 204. System 200 can display the calculated collision probability 322 and 324 together with a representative displacement trajectory indicated by an arrow from object 2 to the current vehicle 204.

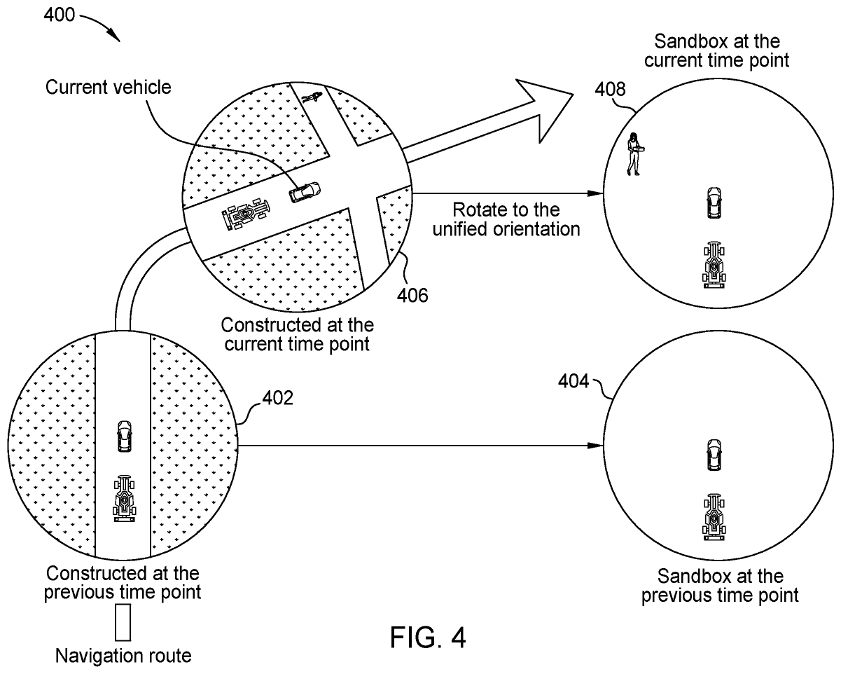

FIG. 4 illustrates example operations 400 of the system 200 to construct a plurality of example sandboxes 402, 404, 406 and 408 with the current vehicle driving along a navigation route using an intelligent vehicle-collision simulation sandbox of one or more disclosed embodiments. System 200 continuously constructs single-object slice sandboxes at the same regular intervals, such as the illustrated sandboxes 402, 404, 406 and 408 (e.g., as illustrated merged with the current vehicle 204). System 200 continuously constructs single-object slice sandboxes while the current vehicle 204 is driving along a navigation route, as schematically illustrated by an arrow from below the sandbox 402 through sandbox 406. As indicated, sandbox 402 is a sandbox constructed at a previous time point and sandbox 406 is a sandbox constructed at a current time point. As illustrated by sandboxes 404 and 408, the generated sandboxes are rotated to align with a driving direction of the current vehicle 204, shown at the central grid of all the sandboxes 402, 404, 406 and 408, for example to display to a user of the current vehicle 204.

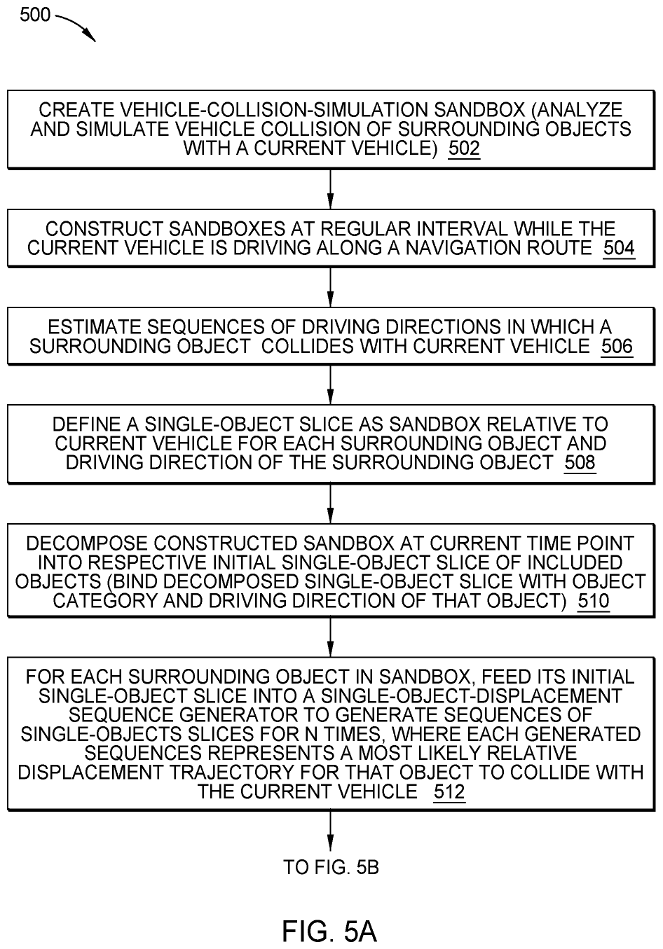

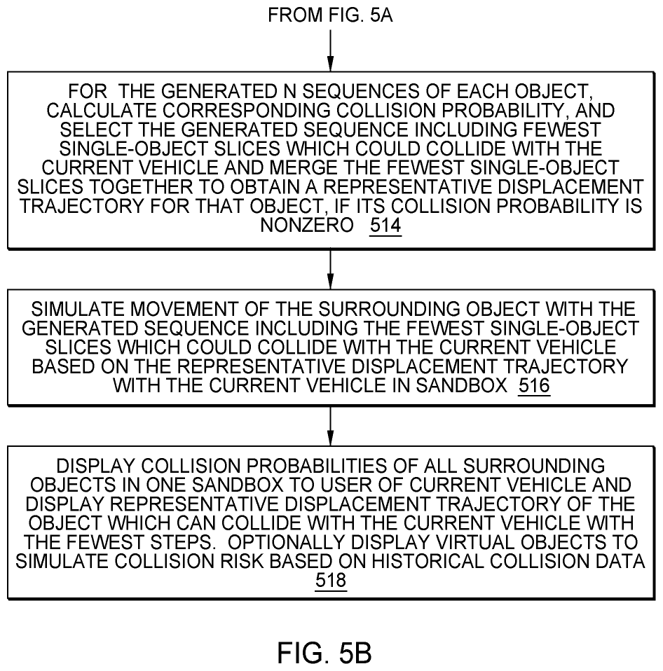

FIGS. 5A and 5B together illustrate example operations of a method 500 for implementing analysis, simulation and collision prediction of a current vehicle and surrounding objects of one or more disclosed embodiments. At block 502 in FIG. 5A, system 200 creates a Vehicle-Collision-Simulation Sandbox 202 of disclosed embodiment. The Vehicle-Collision-Simulation Sandbox 202 simulates each surrounding object 206 to possibly collide with the current vehicle 204 in the sandbox and displays the estimated collision probability of each surrounding object. The Vehicle-Collision-Simulation Sandbox 202 is also referred to as a current sandbox 202, which is constructed at the current time point includes the current vehicle 204 with autonomous driving placed at the most centered grid all the time and the respective initial single-object slices of included objects.

At block 504, system 200 constructs single-object slice sandboxes while the current vehicle 204 is driving along a navigation route, such as illustrated in FIG. 4. At block 506, system 200 estimates one or more sequences of driving directions in which a surrounding object 206 could crash into the current vehicle 204 most directly and quickly through a driving-direction-sequence construction module 210. At block 508, system 200 defines a single-object slice as a sandbox 202, which includes only one of the surrounding objects 206 relative to the current vehicle 204. The single-object slice is bound with the identified category (e.g., car, truck, motorcycle, bike, etc.) and driving direction of the surrounding object.

At block 510, system 200 decomposes the sandbox 202 constructed at the current time point (i.e., current sandbox 202) into respective initial single-object slices of the surrounding objects 206 by a decomposing module. To form a single-object slice, system 200 places each included object into the exact same grid in a blank sandbox and binds the decomposed single-object slice with the category and driving direction of that object.

At block 512, for each surrounding object 206 in the sandbox 202, system 200 feeds its initial single-object slice into a trained single-object-displacement sequence generator 212 to generate sequences of single-object slices for N times, where each generated sequence represents a most likely or probable relative displacement trajectory that the object 206 could collide with the current vehicle 204. In the meantime, to exclude the generated sequences that are irrational or impossible in the current road conditions and make the collision prediction more precise, system 200 uses the driving-direction-sequence construction module 210 to construct the driving-direction sequences of one or more most-quickly-collision routes from the surrounding object 206 to the current vehicle 204 according to the real-time road conditions, for example based on available high definition (HD) map, which system 200 provides to the driving-direction-sequence construction module 210.

Referring to FIG. 5B, at block 514 system 200 calculates, for the generated N sequences of each surrounding object 206, a corresponding collision probability and at the same time, selects the generated sequence including a smallest number of single-object slices which could collide with the current vehicle 204 and merge the single-object slices together to obtain the representative displacement trajectory for that object if its collision probability is nonzero.

At block 516, system 200 simulates the movement of the surrounding object 206 with the generated sequence including the smallest number of single-object slices, which could collide with the current vehicle 204, based on the representative displacement trajectory with the current vehicle 204 in the sandbox.

At block 518, system 200 displays collision probabilities of the surrounding objects 206 in one sandbox 202 to the owner of the current vehicle 204. In addition, system 200 can display the representative displacement trajectory for the object, which might crash into the current vehicle 204 with the smallest number of single-object slices. System 200 optionally can display a detailed step-by-step process of simulating all objects 206 colliding with the current vehicle 204. System 200 optionally can display virtual objects 208 based on historical collision data to the owner of the current vehicle 204.

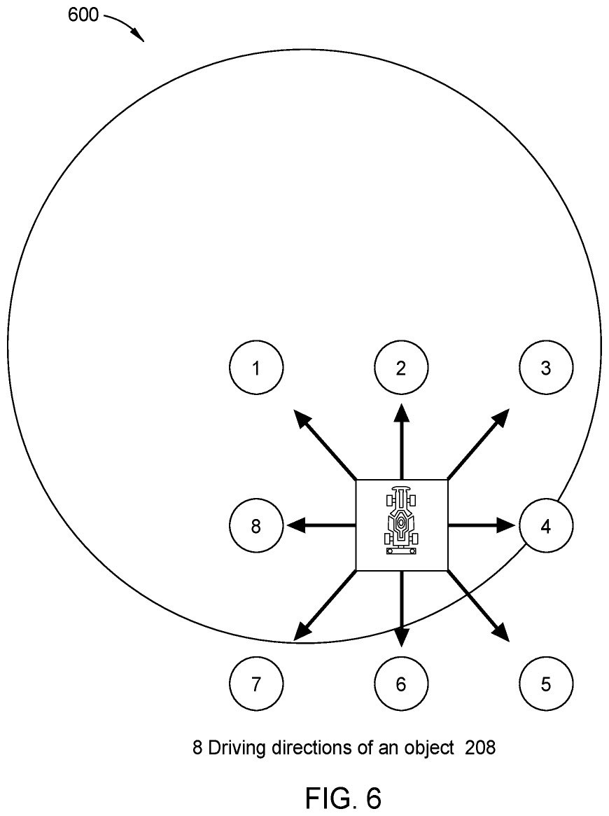

FIG. 6 illustrates multiple example driving directions 600 for an example virtual surrounding object 208, used to implementing analysis, simulation and collision prediction of one or more disclosed embodiments. As shown, eight driving directions 600 #1-8 are defined that can be calculated and applied to the single-object-displacement sequence generator 212 or the driving-direction-sequence construction module 210.

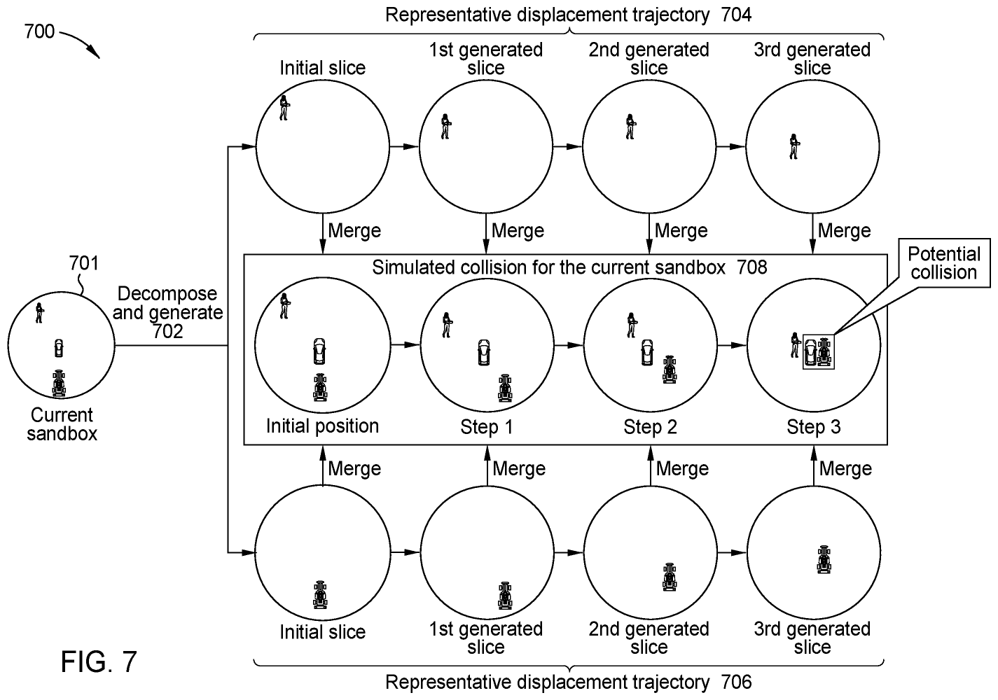

FIG. 7 provides an example process 700 of step-by-step operations of the system 200 for simulating collision in a current sandbox of the surrounding objects 206 to possibly collide with the current vehicle 204 using the vehicle-collision simulation sandbox 202 of one or more disclosed embodiments. System 200 receives an input of a sandbox 701 to decompose and generate (e.g., indicated at the line labeled decompose and generate 702) an illustrated first representative displacement trajectory 704 for a first surrounding object 206 (e.g., a pedestrian) and a second representative displacement trajectory 706 for a second surrounding object 206 (e.g., a vehicle). The first representative displacement trajectory 704 and the second representative displacement trajectory 706 comprise a first series of generated slices (initial, first, second and third generated slices). A simulated collision resulting from a current sandbox 701 comprises system 200 merging each of the respective initial, first, second and third generated slices for respective initial step, step 1, step 2, and step 3 to simulate a possible collision 708 with the current vehicle 204. As shown, a potential collision occurs of the first and/or second object with the current in step 3 with the respective third generated slices merged in illustrated simulated collision (i.e., simulated collision sandboxes 708) for the current sandbox 701. In each of the illustrated steps of simulated collision sandboxes 708, the simulated current vehicle 204 is placed at the most central grid (e.g., the current vehicle 204 remains at the same central location all the time). In the initial slice of the first and second surrounding objects, the respective object (e.g., pedestrian, vehicle) is placed into the generated single-object slice where its geometric center is located. The illustrated sequentially generated slices (e.g., of the illustrated steps initial and steps 1-3) are constructed based upon the simulated movement of the surrounding object at a regular interval (e.g., while the current vehicle 204 is driving along a navigation route) with the one surrounding object 206 illustrated relative to the current vehicle 204 in each generated single-object slice. The merged single-object slices into the current sandbox (e.g., simulated collision sandboxes 708) simulates the relative displacement trajectory along which the surrounding object 206 is most likely or probable to collide with the current vehicle 204.

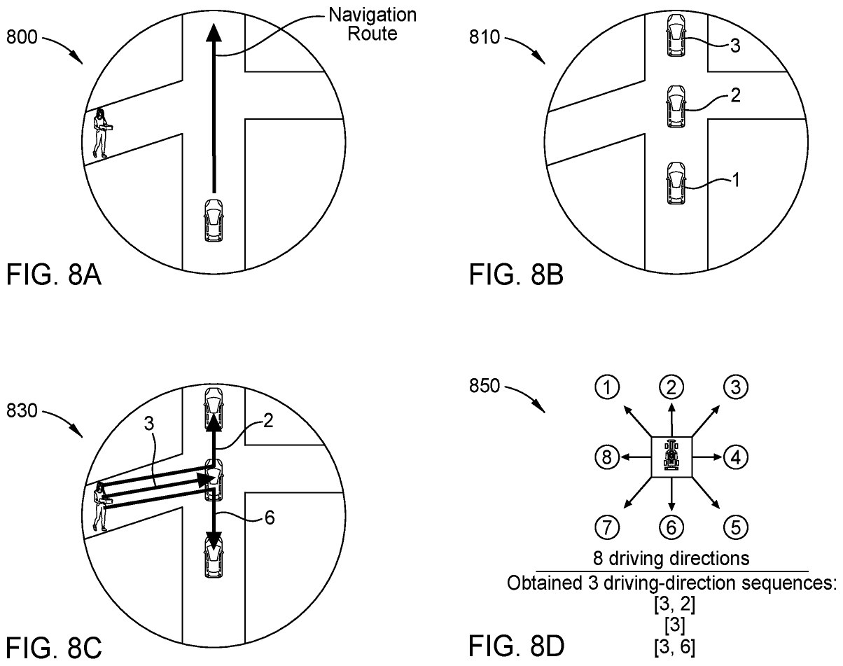

FIGS. 8A, 8B, 8C and 8D together illustrate example operations for simulating collision to generate possible collision routes rendered as sequences of directions along which a surrounding object might collide into the current vehicle most directly and quickly based on a navigation route of the current vehicle of one or more disclosed embodiments. FIG. 8A illustrates for an example operation 800 including a preset navigation route indicated by an arrow for a current vehicle 204 such as used to establish hypothetical collision positions before. after, and exactly at each intersection on the navigation route. FIG. 8B illustrates for an example operation 810 including three hypothetical positions labeled 1, 2, and 3 for the current vehicle 204 along the preset navigation route. For example, when there is no intersection ahead of the current vehicle 204 along the navigation route, the hypothetical collision positions can be set at a spot ahead of the current vehicle along the navigation route. FIG. 8C illustrates for an example operation 830 including three hypothetical collision routes (e.g., top, middle, bottom lines) and related driving directions labeled 2, 3, and 6 for a surrounding object 206 along the preset navigation route. For example, system 200 can take the surrounding object 206 as a starting point and each hypothetical position 1, 2, and 3 of FIG. 8B as the destination, and obtain corresponding collision routes using existing route navigation based on 8 driving directions as illustrated in an operation 850 of FIG. 8D. For example, system 200 can map each collision route (e.g., of three routes of FIG. 8C) to a sequence of driving directions such as provided in FIG. 8D, which illustrates the respective sequence of driving directions for the illustrated three collision routes of FIG. 8C. As shown in FIG. 8D, the respective sequence of driving directions for the illustrated three collision routes include [3, 2], [3] and [3, 6]. For example, system 200 keeps only one direction when two adjacent driving directions in such a sequence are the same direction in the driving-direction sequence. A static direction category and duplicated driving-direction sequences belonging to a same target object are not included or removed in any driving-direction sequence.

In disclosed embodiments, system 200 builds and stores a driving-direction sequence dataset in the Sandbox Data Store 184 based on a historical collision dataset of the Sandbox Data Store using the driving-direction-sequence construction module 210 of disclosed embodiments. System 200 can select two points along a given route navigation, such as a random road and then perform operations to build a driving-direction sequence dataset. For example, system 200 can randomly place virtual objects on the passing roads or forks along the navigation route covered by the partitioned grids of a sandbox 202, and then obtain corresponding driving-direction sequences from the virtual objects to the hypothetical positions of the current vehicle through historical data and save all obtained driving-direction sequences in the Sandbox Data Store 184 as a driving-direction sequences dataset.

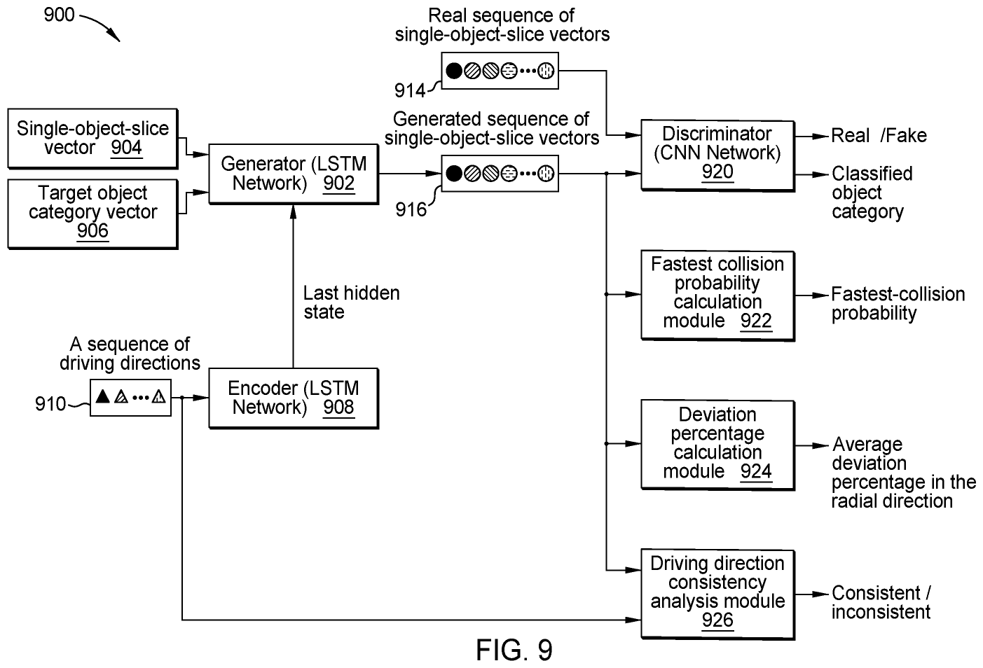

FIG. 9 provides an example generator structure 900 for implementing single-object-displacement sequence generator 212 to perform example operations for analysis, simulation and collision prediction of one or more disclosed embodiments. An illustrated generator 902 comprises for example an instance of the single-object-displacement sequence generator 212 of disclosed embodiments. For example, generator 902 can employ an architecture of generative adversarial networks, in order to generate a sequence of single-object-slice vectors for a given surrounding object 206 in the sandbox 202 based on the object's initial single-object slice. System 200 trains the generator 902 during adversarial training operations to output relative displacement trajectories with rational driving directions for surrounding objects 206 which could collide with the current vehicle 204 in the sandbox 202 (e.g., as quickly as possible.)

In a disclosed embodiment, the single-object-displacement sequence generator 902 comprises a long short-term memory (LSTM) network, which is a type of recurrent neural network (RNN) capable of learning order dependence in sequence prediction applications. For example, the single-object-displacement sequence generator 902 uses the LSTMs to learn, process, and classify sequential data because these networks can learn long-term dependencies between time steps of data. For example, one LSTM application includes video analysis. The generator 902 uses LSTM and samples existing single-object slice vectors 904 to generate a new sequence of single-object-slice vectors based on the input initial single-object slice.

In a disclosed embodiment, an encoder 908 uses LSTM and takes in a sequence of driving directions 910 (e.g., where each direction is represented as a one-hot encoding vector.) For example, the sequence of driving directions 910 input to the encoder 908 is constructed by the driving-direction-sequence construction module 210. A last hidden state of the encoder 908 is fed into the generator 902. The generator 902 concatenates together target (or surrounding) object category vector 906 (e.g., represented as a one-hot encoding vector) and the last hidden state of the encoder 908 as the initial hidden state of the generator 902, and takes in as input an initial single-object slice vector 904 (e.g., represented as a one-hot encoding vector) to generate single-object-slice vectors.

Real sequences of single-object-slice vectors 914 from a training dataset (e.g., stored in the Sandbox Data Store 184) and generated sequences of single-object slice vectors 916 from the generator 902 are input to a discriminator 920. In a disclosed embodiment, the discriminator 920 is a convolutional neural network (CNN) with a highway structure that distinguishes between real sequences of single-object-slice vectors 914 from the training dataset and generated sequences of single-object slice vectors 916 from the generator 902. The discriminator 920 provides a real/fake output and identifies the object categories of the input sequences.

As shown, the generated sequence of single-object slice vectors 916 from the generator 902 is input to a fastest-collision-probability calculation module 922 (e.g., an instance of a Fastest-Collision-Probability Calculation Module 214) that calculates the fastest-collision-probability based on the generated sequence of single-object slices. The generated sequence of single-object slice vectors 916 from the generator 902 is input to a deviation-percentage calculation module 924 (e.g., an instance of a Deviation-Percentage Calculation Module 216) that calculates the average deviation percentage in the radial direction for the generated sequence of single-object slices. The generated sequence of single-object slice vectors 916 from the generator 902 is input to a driving-direction-consistency analysis module 926 (e.g., an instance of a Driving-Direction-Consistency Analysis Module 218) to determine driving direction consistency based on a generated sequence of single-object slices and the related input sequence of driving directions, where a value of one (1) indicates consistency, and a value of zero (0) indicates inconsistency.

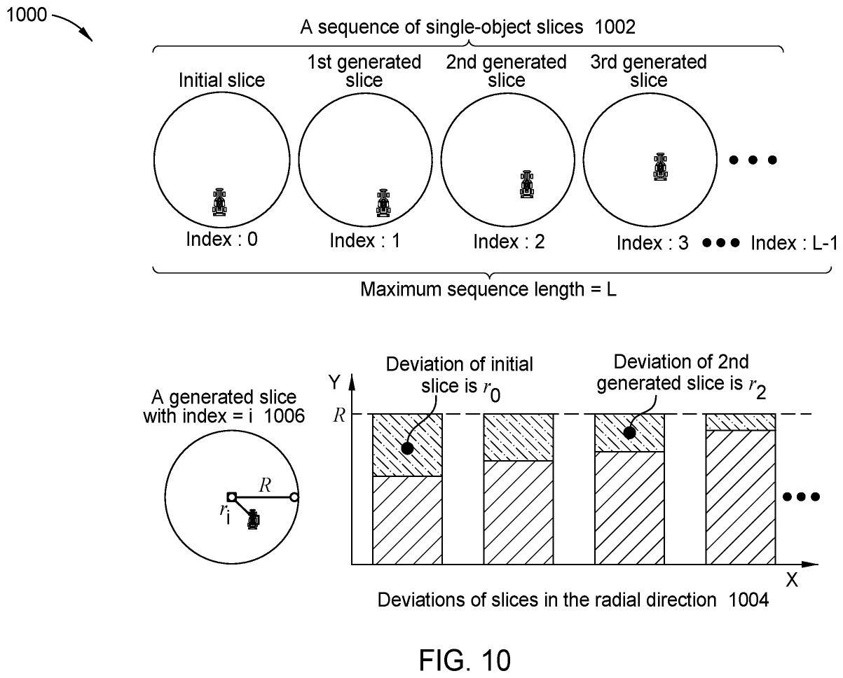

FIG. 10 illustrates example operations 1000 for implementing analysis, simulation and collision prediction of autonomous vehicles of one or more disclosed embodiments. A sequence of single-object slices 1002 includes for one virtual surrounding object 208, as shown an initial slice with index 0, a first generated slice with index 1, a second generated slice with index 2, and a third generated slice with index 3 of a maximum sequence of length =L. The fastest-collision-probability calculation module 214 can use the following equation to calculate the fastest collision probability.

$$𝒫 = [ ( ℒ - 1 ) - {𝒥}_{first\_collision} ] / ℒ$$

Where [symbol] indicates the maximum length of a single-object-slice sequence and [symbol] _{first_collision} indicates the index of the generated single-object slice in the sequence, wherein the target object is driving right into the most central grid in the sandbox at the first time. Let us suppose [symbol] is 10, FIG. 10 shows an example single-object-slice sequence 1002 and [symbol] _{first_collision} is 3.

An illustrated generated slice with index=i 1006 and radius R is shown with a graph of deviations of slices in the radial direction 1004 shown along a horizontal (X) direction and radius shown along a vertical (Y) direction. The deviation-percentage calculation module 216 is used to ensure that each single-object slice in a generated sequence has the target object moving closer to the sandbox center. The module 216 can use the following equation to calculate the average deviation percentage in the radial direction:

$$𝒟 = {\sum }_{i = 1}^{l} ( R - {r}_{i} ) / ( R * l )$$

Where R indicates the radial of the sandbox, rᵢ indicates the distance in the radial direction between the target object (of i-th slice) and the center point of the sandbox (see the illustrated generated slice with index=i 1006 of FIG. 10) and I indicates the length of a single-object-slice sequence. The larger the calculated average deviation percentage (e.g., as illustrated in the graph of FIG. 10, the deviation of initial slice is r₀ and the deviation of second generated slice is r₂), which means the overall relative displacement of the target object is closer to the current vehicle in the sandbox.

The driving-direction-consistency analysis module 218 retrieves the respective driving directions bound to the single-object slices in a generated single-object-slice sequence (e.g., single-object-slice sequence 1002) in turn to form a generated driving-direction sequence, wherein duplicated adjacent driving directions or driving direction static are removed. The driving-direction-consistency analysis module 218 compares the driving directions of the generated driving-direction sequence with the ones of the input driving-direction sequence one by one, starting from the very beginning of the two sequences. If the generated driving-direction sequence is the subset of the input sequence, it indicates driving directions are consistent and the driving-direction-consistency analysis module 218 outputs a value 1; otherwise, the module 218 outputs a value 0.

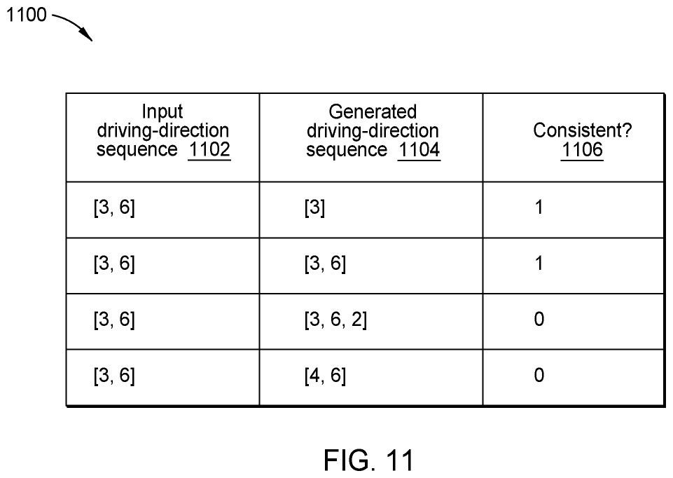

FIG. 11 illustrates example values 1100 from the example operations 1000 of FIG. 10 of one or more disclosed embodiments. FIG. 11 illustrates example values for input driving-direction sequences 1102, generated driving-direction sequences 1104, and calculated consistency 1106 of value 1 where driving directions are consistent and value 0 where driving directions are not consistent.

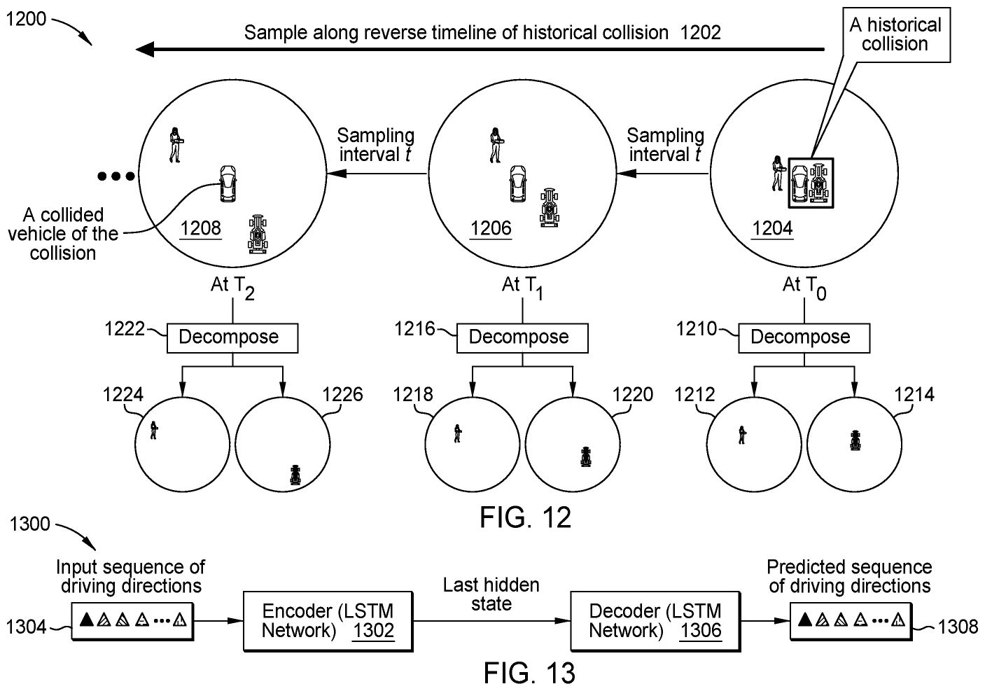

FIG. 12 schematically illustrates example operations 1200 to build a training dataset of one or more disclosed embodiments. As illustrated in FIG. 12, to build a training dataset comprises for each historical vehicle collision take any possible collided current vehicle 204 as the center of the sandbox 202 and sample L historical sandboxes 1204 (e.g., Historical collision At T0), 1206 (e.g., At T1 after first sampling interval), 1208 (e.g., At T2 after second sampling interval), along the reverse timeline of the collision at the sampling interval t with an example surrounding object 206, i.e. pedestrian and vehicle. Each sampled sandbox 1204, 1206, and 1208 is decomposed by a respective decomposing module 1210, 1216, 1222 into respective decomposed single-object slices 1212, 1214; 1218, 1220, and 1224, 1226 for the example surrounding object pedestrian and vehicle 206. For example, refer also to the above described operations 300 of FIG. 3. The decomposed single-object slices belonging to the same surrounding object 206 (e.g., single-object slices 1212, 1218, 1224 or single-object slices 1214, 1220, 1226) involved in the accident are sorted by timeline and saved as a training dataset, (e.g., stored in Sandbox Data Store 184) together with the identified object category and driving direction at the corresponding sampling time point T0, T1, T2. Such a historical sequence of single-object slices indicates a historical relative displacement trajectory of the object 206 in the sandbox 1204 when a collision happened as indicated at T0.

FIG. 13 illustrates example training operations 1300 of example encoder and decoder modules of the system 200 to implement a predicted sequence of driving directions for analysis, simulation and collision prediction of autonomous vehicles of one or more disclosed embodiments. An encoder (e.g., LSTM network) 1302 (e.g., illustrated encoder 908 of FIG. 9), receives an input sequence of driving directions at block 1304 (e.g., from the pre-built driving-direction-sequence database). In the depicted embodiment, the LSTM network encoder 1302 provides an encoded output and a last hidden state to a decoder 1306 (e.g., LSTM network). At block 1308, the LSTM network decoder provides a predicted sequence of driving directions. For example, the training operations can be implemented as follows.

To train the encoder 1302 (e.g., illustrated encoder 908 of FIG. 9), system 200 for example can replicate the encoder 908 to obtain the decoder 1306 and combine the decoder with the encoder to compose an encoder-decoder architecture. For example, use an auto-regression language modeling to train the encoder-decoder model based on every sequence from a pre-built driving-direction-sequence dataset and use cross entropy loss and backpropagation to update its parameters.

To pre-train the generator (e.g., generator 902 of FIG. 9), for example system 200 can use Maximum Likelihood Estimation (MLE) based on all sequences of single-object slices (e.g., represented as one-hot encoding vectors) from the pre-built training dataset and use cross entropy loss and backpropagation to update its parameters. During such pre-training, the generator 902 can take in a zero vector with the same size as the hidden state of the encoder, instead of taking in the real last hidden state of the encoder.

Pre-training the discriminator (e.g., discriminator 920 of FIG. 9), is performed for example by minimizing the cross entropy for its real/fake classification based on the randomly selected real sequences of single-object slices from the pre-built training dataset and the generated sequences from the pre-trained generator. Also minimizing the cross entropy for the object category classification of the discriminator is based on the object category information from the training dataset, which is related to the selected real sequences of single-object slices and can use backpropagation to update the parameters of the discriminator.

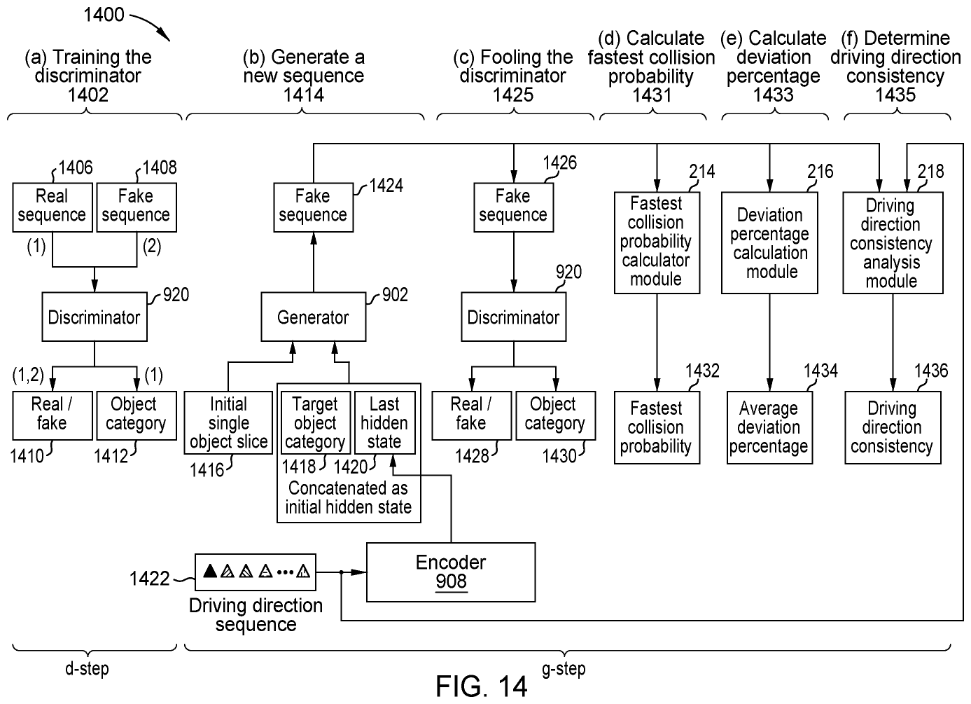

FIG. 14 provides example adversarial training operations 1400 of system 200 for simulating collision in an example sandbox using an intelligent vehicle-collision simulation sandbox of one or more disclosed embodiments. At operation (a) 1402, system 200 begins with training the discriminator (e.g., discriminator 920 of FIG. 9); the adversarial training is similar to pre-training the discriminator. The discriminator 920 learns to distinguish between real sequences 1406 or fake sequences 1408 of single-object slices to classify a real sequence or a fake sequence 1410 with the related object category 1412 for the real sequence. The real sequences 1406 fed into the discriminator 920 for adversarial training can be based on selected real sequences of single-object slices from the pre-built training dataset. Selected fake sequences of single-object slices are generated from an illustrated g-step of FIG. 14 for training the generator 902.

At operation (b) 1414 system 200 generates a new sequence, the encoder (e.g., encoder 908 of FIG. 9) takes in a random sequence 1422 from the driving-direction-sequence dataset, wherein the first driving direction is the same as the one bound to a randomly-selected initial single-object slice (e.g., from the training dataset of the Sandbox Data Store 184). The generator 902 generates a fake sequence 1424 of single-object-slice vectors based on an input initial single-object slice 1416 (represented as a one-hot encoding vector), a target object category 1418, and a last hidden state 1420. For example, the generator 902 concatenates the last hidden state 1420 of the encoder 908 and the target object category (represented as a one-hot encoding vector) 1418 bound to the initial single-object slice 1416 as the initial hidden state of the generator 902, and takes in as input the initial single-object slice 1416. At operation (c) 1425, the generator tries to generate sequences indistinguishable from real ones and classifiable as target object categories by the discriminator. At operation (d) 1431, the fastest-collision-probability calculation module 214 calculates the fastest collision probabilities. At operation (e) 1433, the deviation-percentage calculation module 216 calculates the average deviation percentages in the radial direction. At operation (f) 1435, the driving-direction-consistency analysis module 218 takes in the generated sequences and the input driving-direction sequences to determine the driving-direction consistencies.

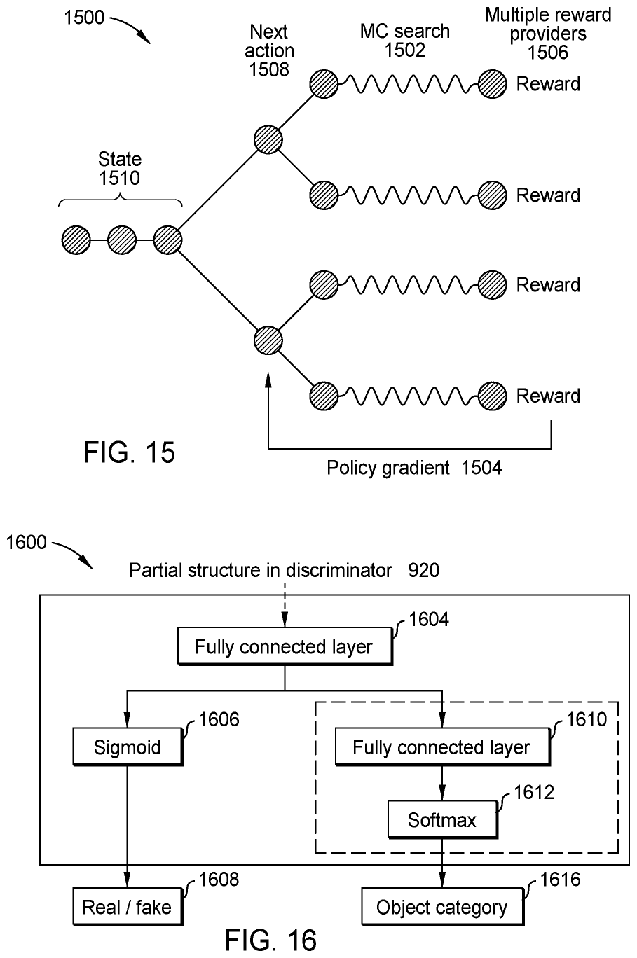

In each d-step (e.g., d-steps corresponding to operation (a) 1402) of adversarial training, both the fake sequences 1408 of single-object-slice vectors (generated by the current generator 902) and the real sequences 1406 (from the training dataset in Sandbox Data Store 184) are used to minimize the cross entropy for the discriminator 920. In each g-step, the policy gradient 1504 of FIG. 15 can be used to update the generator's parameters. The encoder 908 is involved in both the g-steps and the d-steps to keep encoding input driving-direction sequences and delivering its last hidden states. The adversarial training can be continued until the generator 902 converges.

Referring also to FIG. 15, an example policy gradient 1500 is schematically illustrated for adversarial training of the generator 902 of system 200 of one or more disclosed embodiments. In a disclosed embodiment, the illustrated policy gradient 1500 relies on a corresponding action-value function of a single-object-slice sequence. During the adversarial training, the generator 902 is trained by policy gradient 1500 where the final reward signal is provided by reward providers 1506 comprising the discriminator 920, the fastest-collision-probability calculation module 214, the deviation-percentage calculation module 216 and the driving-direction-consistency analysis module 218 and is passed back to an intermediate action value (e.g., next action 1508) via a Monte Carlo (MC) search 1502 based on a state 1510.

The following represents an example action-value function of a single-object-slice sequence used by system 200.

$${Q}^{{G}_{θ}} ( s = {Y}_{1 : t - 1} , a = {y}_{t} ) = \{ \begin{matrix}\frac{1}{N} {\sum }_{n = 1}^{N} ( {λ}_{1} * {D}_{ϕ} ( {Y}_{1 : T}^{n} ) + {λ}_{2} * {D}_{{obj}_{ϕ}} ( {Y}_{1 : T}^{n} ) + {λ}_{3} * 𝒫 ( {Y}_{1 : T}^{n} ) + {λ}_{4} * 𝒟 ( {Y}_{1 : T}^{n} ) + {λ}_{5} * 𝒞 ( {Y}_{1 : T}^{n} s ) ) {Y}_{1 : T}^{n} ∈ {MC}^{{G}_{β}} ( {Y}_{1 : t} ; N ) & for t < T \\ {λ}_{1} * {D}_{ϕ} ( {Y}_{1 : t} ) + {λ}_{2} * {D}_{{obj}_{ϕ}} ( {Y}_{1 : t} ) + {λ}_{3} * 𝒫 ( {Y}_{1 : t} ) + {λ}_{4} * 𝒟 ( {Y}_{1 : t} ) + {λ}_{5} * 𝒞 ( {Y}_{1 : t} s ) & for t = T\end{matrix}$$

### Where:

D_{ϕ}(Y_{1:T}ⁿ) is the estimated probability of being real by the discriminator 920 as the reward.
D_{obj}_{_{ϕ}}(Y_{1:T}ⁿ) is the estimated probability of being target object category by the discriminator 920 as the reward.
[symbol] (Y_{1:T}ⁿ) is the calculated fastest collision probability by the fastest-collision-probability calculation module 214 as the reward.
[symbol] (Y_{1:T}ⁿ) is the calculated average deviation percentage in the radial direction by the deviation-percentage calculation module 216 as the reward.
[symbol] (Y_{1:T}ⁿ, [symbol] ) is the analyzed driving-direction consistency by the driving-direction-consistency analysis module 218 as the reward, wherein [symbol] indicates an input sequence of driving directions from the pre-built driving-direction-sequence dataset.
λ₁, λ₂, λ₃, λ₄ and λ₆ are the hyper-parameters that control the relative importance of factors respectively, and λ₁+λ₂+λ₃+λ₄+λ₅=1. System 200 uses λ₁=0.2, λ₂=0.1, λ₃=0.3, λ₄=0.1 and λ₅=0.3.
T is the maximum length of generated single-object-slice sequences.

FIG. 16 illustrates an example partial structure 1600 for implementing the discriminator 920 of disclosed embodiments. In a disclosed embodiment, the discriminator 920 can adopt an internal structure of Sequence Generative Adversarial Nets (SeqGAN) for example with policy gradient 1500 with an extended output part comprising a fully connected layer 1604, a Sigmond function 1606. For example, the SeqGAN can bypass generator differentiation problem by directly performing gradient policy update. The RL reward signal comes from the GAN discriminator judged on a complete sequence, and is passed back to the intermediate state-action steps using the Monte Carlo (MC) search 1502 of FIG. 15.

In a disclosed embodiment, the discriminator 920 includes an added fully connected layer 1610 and a Softmax layer function 1612 to provide the classification of object category 1616, such as vehicle or pedestrian. The Softmax function 1612 can be used as the last neural network-based classifier activation function of the discriminator 920. The Sigmoid function 1606 can perform the role of an activation function used to add non-linearity in the machine learning discriminator 920. As shown, the Sigmoid function 1606 can determine which value to pass or not to pass as output Real/fake 1608.

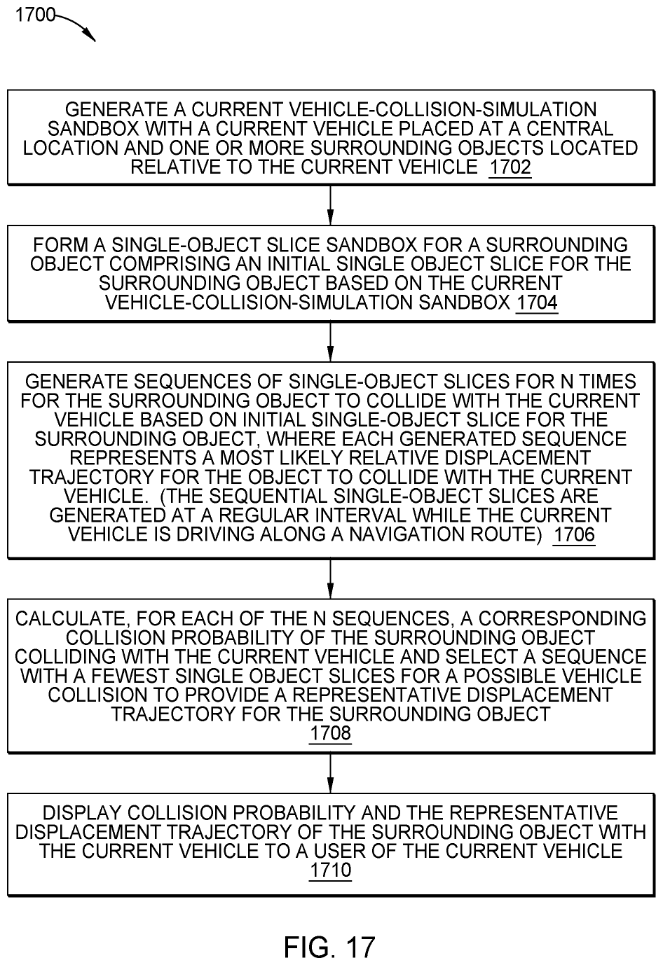

Referring now to FIG. 17, there are shown example operations of a method 1700 of disclosed embodiments starting at block 1702. At block 1702, system 200 generates a current vehicle-collision-simulation sandbox 202 with a current vehicle 204 centrally located and one or more surrounding objects 206 located relative to the current vehicle. Example operations for one surrounding object 206 are described as follows. At block 1704, system 200 forms a single-object slice sandbox for a surrounding object comprising an initial single-object slice for the surrounding object based on the current vehicle-collision-simulation sandbox 202. At block 1706, system 200 generates sequences of single-object slices for N times for the surrounding object 206 to collide with the current vehicle based on the initial single-object slice for the surrounding object, where each generated sequence represents a most likely or probable relative displacement trajectory for the surrounding object to collide with the current vehicle. The single-object slices for each sequence are generated at a regular interval while the current vehicle is driving along a navigation route. At block 1708, system 200, calculates for each of the N sequences, a corresponding collision probability of the surrounding object 206 colliding with the current vehicle and selects a generated sequence including a fewest single-object slices for a possible vehicle collision of the surrounding object with the current vehicle to provide a representative displacement trajectory of the surrounding object. System 200 merges each sequential single-object slice for the surrounding object with the current vehicle-collision-simulation sandbox to simulate a vehicle collision of the surrounding object with the current vehicle. At block 1710, system 200 displays the collision probability and the representative displacement trajectory of the surrounding object with the current vehicle to a user of the current vehicle.

While the foregoing is directed to embodiments of the present invention, other and further embodiments of the invention may be devised without departing from the basic scope thereof, and the scope thereof is determined by the claims that follow.

What is claimed is:

1. A method comprising:
generating a current vehicle-collision-simulation sandbox comprising a current vehicle and at least one surrounding object;
forming a single-object slice sandbox for the at least one surrounding object comprising an initial single-object slice for the at least one surrounding object based on the current vehicle-collision-simulation sandbox;
generating multiple sequences of single-object slices for the at least one surrounding object to collide with the current vehicle based on the initial single-object slice for the at least one surrounding object;
calculating, for each of the multiple sequences, a corresponding collision probability of the at least one surrounding object colliding with the current vehicle;
generating a representative displacement trajectory of the at least one surrounding object with the current vehicle based on the multiple sequences; and
displaying the corresponding calculated collision probabilities and the representative displacement trajectory of the at least one surrounding object to a user of the current vehicle.

2. The method of claim 1, wherein generating the representative displacement trajectory of the at least one surrounding object with the current vehicle comprises selecting one of the multiple sequences that includes a smallest number of the single-object slices.

3. The method of claim 1, wherein each of the multiple sequences represents a most probable relative displacement trajectory for the surrounding object to collide with the current vehicle.

4. The method of claim 1, wherein the current vehicle-collision-simulation sandbox comprises a grid-partitioned circular range with the current vehicle placed at a centrally located grid and each surrounding object placed into a grid of a geometric center of the surrounding object relative to the current vehicle.

5. The method of claim 1, wherein the single-object slice of the multiple sequences of single-object slices for the at least one surrounding object comprises a sandbox comprising only one surrounding object relative to the current vehicle.

6. The method of claim 1, wherein the single-object slice of the multiple sequences of single-object slices for the at least one surrounding object is bound to an object category and a driving direction of the surrounding object.

7. The method of claim 1, wherein generating the multiple sequences of single-object slices for the at least one surrounding object further comprises constructing sandboxes at a set regular interval while the current vehicle is driving along a navigation route.

8. The method of claim 1, further comprises simulating movement of the at least one surrounding object in the current vehicle-collision-simulation sandbox based on the representative displacement trajectory of the multiple sequences of single-object slices for the surrounding object.

9. The method of claim 1, wherein generating the multiple sequences of single-object slices for the at least one surrounding object further comprises collecting historical collision data from a historical collision dataset to generate the representative displacement trajectory.

10. The method of claim 1, wherein generating multiple sequences of single-object slices for the at least one surrounding object further comprises training a single-object-displacement sequence generator based on a historical collision dataset of historical collisions.

11. A system, comprising:
a processor; and
a memory, wherein the memory includes a computer program product configured to perform operations for implementing an intelligent vehicle-collision simulation sandbox, the operations comprising:
generating a current vehicle-collision-simulation sandbox comprising a current vehicle and at least one surrounding object;
forming a single-object slice sandbox for the at least one surrounding object comprising an initial single-object slice for the at least one surrounding object based on the current vehicle-collision-simulation sandbox;
generating multiple sequences of single-object slices for the at least one surrounding object to collide with the current vehicle based on the initial single-object slice for the at least one surrounding object;
calculating, for each of the multiple sequences, a corresponding collision probability of the at least one surrounding object colliding with the current vehicle;
generating a representative displacement trajectory of the at least one surrounding object with the current vehicle based on the multiple sequences; and
displaying the corresponding calculated collision probabilities and the representative displacement trajectory of the at least one surrounding object to a user of the current vehicle.

12. The system of claim 11, wherein the single-object slice of the multiple sequences of single-object slices for the at least one surrounding object is bound to an object category and a driving direction of the surrounding object.

13. The system of claim 11, wherein each of the multiple sequence represents a most probable relative displacement trajectory for the at least one surrounding object to collide with the current vehicle.

14. The system of claim 11, wherein the current vehicle-collision-simulation sandbox comprises a grid-partitioned circular range with the current vehicle placed at a centrally located grid and each surrounding object placed into a grid of a geometric center of the surrounding object relative to the current vehicle.

15. The system of claim 11, wherein generating the multiple sequences of single-object slices for the at least one surrounding object further comprises training a single-object-displacement sequence generator based on a historical collision dataset of historical collisions.

16. A computer program product for implementing an intelligent vehicle-collision simulation sandbox, the computer program product comprising:
a computer-readable storage medium having computer-readable program code embodied therewith, the computer-readable program code executable by one or more computer processors to perform an operation comprising:
generating a current vehicle-collision-simulation sandbox comprising a current vehicle and at least one surrounding object;
forming a single-object slice sandbox for the at least one surrounding object comprising an initial single-object slice for the at least one surrounding object based on the current vehicle-collision-simulation sandbox;
generating multiple sequences of single-object slices for the at least one surrounding object to collide with the current vehicle based on the initial single-object slice for the at least one surrounding object;
calculating, for each of the multiple sequences, a corresponding collision probability of the at least one surrounding object colliding with the current vehicle;
generating a representative displacement trajectory of the at least one surrounding object with the current vehicle based on the multiple sequences; and
displaying the corresponding calculated collision probabilities and the representative displacement trajectory of the at least one surrounding object to a user of the current vehicle.

17. The computer program product of claim 16, wherein generating the multiple sequences of single-object slices comprises providing a trained single-object-displacement sequence generator to generate the multiple sequences.

18. The computer program product of claim 16, wherein each of the multiple sequences represents a most probable relative displacement trajectory for the at least one surrounding object to collide with the current vehicle.

19. The computer program product of claim 16, wherein the current vehicle-collision-simulation sandbox comprises a grid-partitioned circular range with the current vehicle placed at a centrally located grid and each surrounding object placed into a grid of a geometric center of the surrounding object relative to the current vehicle.

20. The computer program product of claim 16, wherein generating the multiple sequences of single-object slices for the at least one surrounding object further comprises training a single-object-displacement sequence generator based on a historical collision dataset of historical collisions.
